(19) United States
(12) Patent Application Publication
(10) Pub. No.: US 2026/0175144 A1
(43) Pub. Date: Jun. 25, 2026

(54) SUBSTRATE PROCESSING APPARATUS AND SUBSTRATE PROCESSING METHOD

(71) Applicants: SEMES CO., LTD., Cheonan-si (KR); UIF (University Industry Foundation), Yonsei University, Seoul (KR)

(72) Inventors: Jin Kyu KIM, Suwon-si (KR); Jae Hyeok YU, Hwaseong-si (KR); Hyeong Soo PARK, Yongin-si (KR); Hyung Suk LEE, Seoul (KR); Donyoung KANG, Seoul (KR); Min Hyeong PARK, Seoul (KR); Jun Hyub KIM, Seoul (KR)

(73) Assignees: SEMES CO., LTD., Cheonan-si (KR); UIF (University Industry Foundation), Yonsei University, Seoul (KR)

(21) Appl. No.: 19/421,688

(22) Filed: Dec. 16, 2025

(30) Foreign Application Priority Data
Dec. 20, 2024 (KR) 10-2024-0193154

(51) Int. Cl. B01D 21/28; B01D 19/00; B01D 21/30; H10P 72/00

(52) U.S. Cl. CPC B01D 21/283; B01D 19/0063; B01D 19/0078; B01D 21/302; H10P 72/0404

(57) ABSTRACT

Provided is an apparatus of processing a substrate. The apparatus includes: a treating chamber for processing a substrate with a treatment liquid; and a treatment liquid supply unit for supplying the treatment liquid to the treating chamber, in which the treatment liquid supply unit includes: a treatment liquid tank for storing the treatment liquid; a treatment liquid supply line for connecting the treatment liquid tank and the treating chamber; and an acoustic wave applying module which is installed in the treatment liquid supply line and applies an acoustic wave to the treatment liquid supply line to improve cleanliness of the treatment liquid. Accordingly, foreign substances, such as particles and bubbles, in the treatment liquid may be removed by applying acoustic waves to the treatment liquid.

### CROSS-REFERENCE TO RELATED APPLICATION

This application claims priority to and the benefit of Korean Patent Application No. 10-2024-0193154 filed in the Korean Intellectual Property Office on Dec. 20, 2024, the entire contents of which are incorporated herein by reference.

### TECHNICAL FIELD

The present invention relates to a substrate processing apparatus and a substrate processing method, and more specifically, to a substrate processing apparatus that processes a substrate by removing particles and bubbles in a treatment liquid by applying acoustic waves to a treatment liquid supply line.

### BACKGROUND ART

Since particles in the treatment liquid directly adversely affect performance and yield in the semiconductor manufacturing process, it is very important to remove the particles. In the semiconductor manufacturing process, the treatment liquid is used for various processes, such as wafer cleaning, etching, and thin film deposition, and in this process, the cleanliness of the treatment liquid greatly affects the quality of the product. In particular, particles, bubbles, and the like (hereinafter, referred to as “particles and the like”) present in the treatment liquid may cause defects on a wafer surface or cause process defects and must be removed.

A filter is generally used to remove particles and the like. The filter plays a role of filtering and removing particles and the like in the treatment liquid, but has a disadvantage in that pressure loss occurs in this process. Pressure loss increases the performance demand of the pump supplying the treatment liquid, resulting in a need for a high-performance pump. High-performance pumps can lead to increased cost and increased energy consumption, thereby lowering process efficiency.

In addition, there is a method of using a separate device that removes particles and the like in addition to the filter. In this case, the removal effect of particles and the like may be increased, but a problem occurs in that the structure of the semiconductor manufacturing apparatus becomes complicated. Increasing the complexity of the apparatus causes difficulties in design and maintenance, and there is a possibility of lowering the stability and efficiency of the production line.

### SUMMARY OF THE INVENTION

The present invention has been made in an effort to provide a substrate processing apparatus and method capable of improving cleanliness of a treatment liquid while preventing a pressure of a supplied treatment liquid from being lost.

The present invention has also been made in an effort to provide a substrate processing apparatus and method capable of improving cleanliness of a treatment liquid while eliminating complexity of a process and an apparatus structure.

The present invention has also been made in an effort to provide a substrate processing apparatus and method capable of removing foreign substances, such as particles and bubbles, in a treatment liquid by applying acoustic waves to a treatment liquid.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a treating chamber for processing a substrate with a treatment liquid; and a treatment liquid supply unit for supplying the treatment liquid to the treating chamber, wherein the treatment liquid supply unit may includes: a treatment liquid tank for storing the treatment liquid; a treatment liquid supply line for connecting the treatment liquid tank and the treating chamber; and an acoustic wave applying module which is installed in the treatment liquid supply line and applies an acoustic wave to the treatment liquid supply line to improve cleanliness of the treatment liquid.

According to the exemplary embodiment of the present invention, wherein the acoustic wave applying module may includes: a case surrounding the treatment liquid supply line; an acoustic wave generating part installed in the case; and a medium provided inside the case.

According to the exemplary embodiment of the present invention, wherein the acoustic wave generating part may be provided to form a standing wave in the treatment liquid supply line.

According to the exemplary embodiment of the present invention, wherein the acoustic wave generating part is provided in plural and may be continuously installed.

According to the exemplary embodiment of the present invention, wherein the acoustic wave generating part may include a phase adjusting unit provided to adjust a phase of the acoustic wave.

According to the exemplary embodiment of the present invention, wherein the case is provided in a cylindrical shape with a curved surface, and the acoustic wave generating part is made of a polymer material having flexibility and piezoelectricity, and may be installed on the curved surface.

According to the exemplary embodiment of the present invention, wherein the case is provided in a cylindrical shape with a curved surface, and the acoustic wave generating part is made of an inorganic crystal thin film material having piezoelectricity and may be installed on the curved surface.

According to the exemplary embodiment of the present invention, the apparatus may further include a controller, wherein the controller may determines a wavelength of an acoustic wave generated by the acoustic wave generating part according to a type of particles present in the treatment liquid.

According to the exemplary embodiment of the present invention, the apparatus may further include a controller, wherein the controller may controls the acoustic wave applying module to perform: a collection operation of collecting particles and bubbles in the treatment liquid by generating an acoustic wave in the acoustic wave generating part when supplying the treatment liquid; and a moving operation of moving the collected particles and bubbles by adjusting a phase of the acoustic wave in the phase adjusting unit.

According to the exemplary embodiment of the present invention, wherein after the moving operation, the acoustic wave applying module may be controlled to perform a removal operation of removing the particles and bubbles moved after collection.

An exemplary embodiment of the present disclosure, a method of processing a substrate, the method comprising: a treatment liquid supplying operation of supplying a treatment liquid to process a substrate; and a substrate processing operation of processing the substrate with the treatment liquid, wherein the treatment liquid supplying operation further may includes a collection operation of collecting particles and bubbles in the treatment liquid by applying an acoustic wave to the treatment liquid while supplying the treatment liquid.

According to the exemplary embodiment of the present invention, wherein in the treatment liquid supplying operation, the treatment liquid is supplied through a treatment liquid supply line, and in the collection operation, an acoustic wave generated by an acoustic wave generating part may be transmitted to the treatment liquid supply line through a medium.

According to the exemplary embodiment of the present invention, wherein the acoustic wave applied in the collection operation may be provided to form a standing wave in the treatment liquid supply line.

According to the exemplary embodiment of the present invention, wherein in the collection operation, a frequency of the acoustic wave may be changed according to the particles and bubbles to be collected.

According to the exemplary embodiment of the present invention, wherein the treatment liquid supplying operation further may includes a moving operation of adjusting a phase of the acoustic wave to move the collected particles and bubbles, after the collection operation.

According to the exemplary embodiment of the present invention, the apparatus may further include after the moving operation, a removal operation of removing the particles and bubbles moved after collection to the outside of the treatment liquid supply line.

An exemplary embodiment of the present disclosure, an apparatus for processing a substrate, the apparatus comprising: a treating chamber for processing a substrate with a treatment liquid; and a treatment liquid supply unit for supplying the treatment liquid to the treating chamber, wherein the treatment liquid supply unit includes: a treatment liquid tank for storing the treatment liquid; a treatment liquid supply line for connecting the treatment liquid tank and the treating chamber; and an acoustic wave applying module which is installed in the treatment liquid supply line and applies an acoustic wave to the treatment liquid supply line to improve cleanliness of the treatment liquid; a removal line for removing particles collected by the acoustic wave applying module to the outside; and a controller, the acoustic wave applying module includes: a case surrounding the treatment liquid supply line; an acoustic wave generating part installed in the case; a phase adjusting unit configured to adjust a phase of the acoustic wave, and a medium provided inside the case, the acoustic wave generating part is provided to form a standing wave in the treatment liquid supply line and adjust a phase of the acoustic wave, and the controller controls the acoustic wave applying module to perform: a collection operation of collecting particles and bubbles in the treatment liquid by generating an acoustic wave in the acoustic wave generating part when supplying the treatment liquid; and a moving operation of moving the collected particles and bubbles to an inner wall of the treatment liquid supply line by adjusting a phase of the acoustic wave in the phase adjusting unit.

According to the exemplary embodiment of the present invention, wherein the acoustic wave generating part may be provided to form a standing wave in the treatment liquid supply line.

According to the exemplary embodiment of the present invention, wherein the case is provided in a cylindrical shape with a curved surface, and the acoustic wave generating part is made of a polymer material or an inorganic crystal thin film material having flexibility and piezoelectricity, and may be installed on the curved surface.

According to the exemplary embodiment of the present invention, wherein a wavelength of an acoustic wave generated by the acoustic wave generating part may be determined according to a type of particles and bubbles present in the treatment liquid.

According to the exemplary embodiment of the present invention, it is possible to improve cleanliness of a treatment liquid while preventing a pressure of a supplied treatment liquid from being lost.

Further, according to the exemplary embodiment of the present invention, it is possible to improve cleanliness of a treatment liquid while eliminating complexity of a process and an apparatus structure.

Further, according to the exemplary embodiment of the present invention, it is possible to remove foreign substances, such as particles and bubbles, in a treatment liquid by applying acoustic waves to a treatment liquid.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a diagram schematically illustrating an exemplary embodiment of a liquid treating chamber of FIG. 1.

FIG. 3 is a diagram schematically illustrating an exemplary embodiment of a treatment liquid supply unit.

FIG. 4 is a diagram schematically illustrating an exemplary embodiment of an acoustic wave applying module of FIG. 3.

FIG. 5 is a diagram schematically illustrating another exemplary embodiment of the acoustic wave applying module of FIG. 3.

FIG. 6 is a diagram illustrating an effect on particles and the like in a treatment liquid when a standing wave is formed in the treatment liquid.

FIG. 7 is a flowchart illustrating a substrate processing method according to an exemplary embodiment of the present invention.

FIG. 8 is a diagram illustrating a process of moving particles and the like in a moving operation.

FIG. 9 is a diagram schematically illustrating a state in which a plurality of acoustic wave applying modules is installed.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as a target to be treated. However, the technical idea of the present invention may be applied to devices used for treating other types of substrates other than wafers as objects to be treated. Hereinafter, an exemplary embodiment of the present invention will be described with reference to the accompanying drawings.

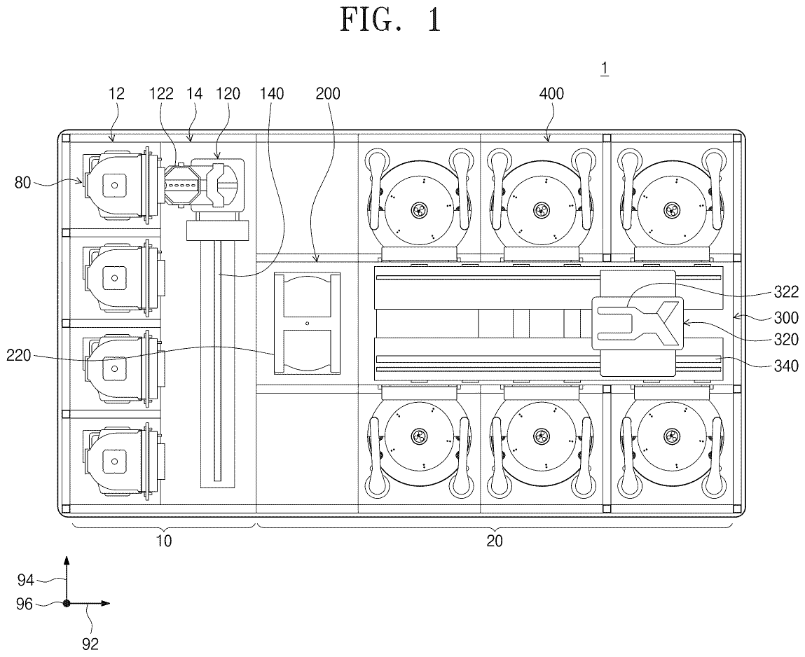

FIG. 1 is a top plan view schematically illustrating a substrate processing apparatus according to an exemplary embodiment of the present invention.

Referring to FIG. 1, a substrate processing apparatus includes an index module 10, a treating module 20, and a controller 30. In the exemplary embodiment, the index module 10 and the treating module 20 are disposed along one direction. Hereinafter, the direction in which the index module 10 and the treating module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal direction is the second direction 94 is provided within the index frame 14, and the index robot 120 may be provided to be movable on the guide rail 140. The index robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the vertical direction, and the hands 122 may move forward and backward independently of each other.

The treating module 20 includes a buffer unit 200, a transfer chamber 300, and a treating chamber 400. The buffer unit 200 provides a space in which the substrate W loaded into the treating module 20 and the substrate W unloaded from the treating module 20 stay temporarily. The treating chamber 400 performs a processing process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on opposite sides of the transfer chamber 300. At each of opposite sides of the transfer chamber 300, the liquid treating chambers 400 may be provided in an array of A×B (each of A and B is 1 or a natural number greater than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

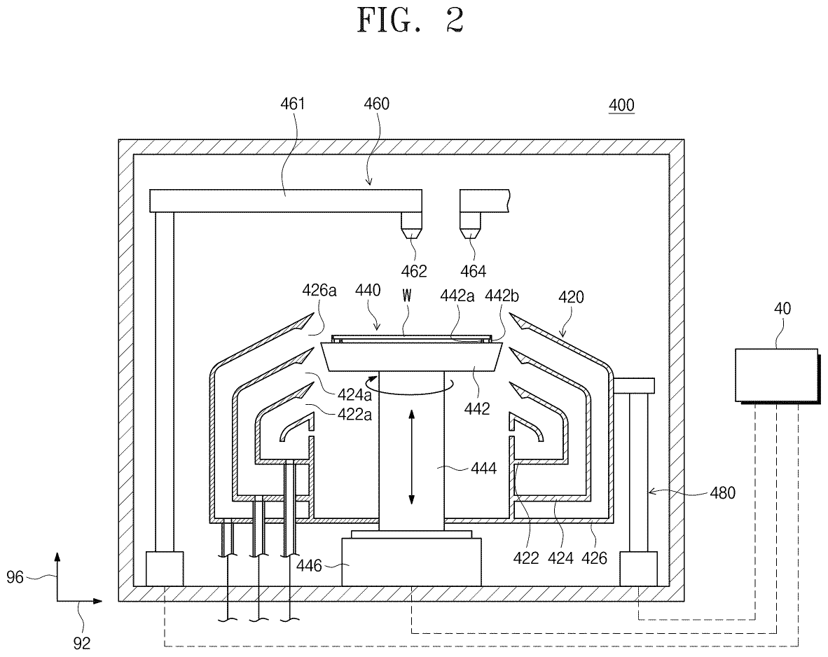

FIG. 2 is a diagram schematically illustrating the exemplary embodiment of the liquid treating chamber 400 of FIG. 1. Referring to FIG. 2, the liquid treating chamber 400 includes a housing 410, a cup 420, a support unit 440, a nozzle unit 460, a lifting unit 480, a treatment liquid supply unit 1000, and a controller.

The housing 410 is provided in a generally rectangular parallelepiped shape. The cup 420, the support unit 440, and the treatment liquid supply unit 1000 are disposed within the housing 410.

The cup 420 has a treatment space with an open top, and the substrate W is liquid-processed in the treatment space. The support unit 440 supports the substrate W in the treatment space. The treatment liquid supply unit 1000 supplies the treatment liquid onto the substrate W supported by the support unit 440. The liquid may be provided in a plurality of types, and may be sequentially supplied onto the substrate W. The lifting unit 480 adjusts a relative height between the cup 420 and the support unit 440.

According to an example, the cup 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 440. As the liquid treating process proceeds, the treatment liquid scattered by the rotation of the substrate W is introduced into the recovery space through the inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a support plate 442 and a drive shaft 444. An upper surface of the support plate 442 may be provided in a generally circular shape, and may have a diameter larger than a diameter of the substrate W. Further, a support pin 442a supporting the rear surface of the substrate W is provided at the center of the support plate 442, and the upper end of the support pin 442a is provided to protrude from the support plate 442 so that the substrate W is spaced apart from the support plate 442 by a predetermined distance. A chuck pin 442b is provided at an edge portion of the support plate 442. The chuck pin 442b is provided to protrude upward from the support plate 442, and supports the side portion of the substrate W so that the substrate W does not deviate from the support unit 440 when the substrate W is rotated. The drive shaft 444 is driven by the driver 446, is connected to the center of the bottom surface of the substrate W, and rotates the support plate 442 about its central axis.

The nozzle unit 460 includes a first nozzle 462 and a second nozzle 464. The first nozzle 462 supplies the treatment liquid onto the substrate W. The treatment solution may be a liquid having a temperature higher than room temperature. According to an example, the treatment solution may be an aqueous phosphoric acid solution. The aqueous phosphoric acid solution may be a mixture of phosphoric acid and water. Optionally, the aqueous phosphoric acid solution may further contain other substances. For example, the other material may be silicon. The second nozzle 464 supplies water onto the substrate W. The water may be pure water or deionized water.

The first nozzle 462 and the second nozzle 464 are supported by different arms 461, respectively, and these arms 461 may be moved independently. Optionally, the first nozzle 462 and the second nozzle 464 may be mounted on the same arm and moved at the same time.

Optionally, the nozzle unit 460 may further include one or a plurality of nozzles in addition to the first nozzle 462 and the second nozzle 464. The added nozzle may supply another type of treatment liquid to the substrate. For example, another type of treatment liquid may be an acid solution or a base solution for removing foreign substances on the substrate. In addition, another type of treatment liquid may be alcohol having surface tension lower than water. For example, the alcohol may be isopropyl alcohol.

The lifting unit 480 moves the cup 420 in the up and down direction. By the up and down movement of the cup 420, a relative height between the cup 420 and the substrate W is changed. Accordingly, the recovery containers 422, 424, and 426 for recovering the treatment solution are changed according to the type of liquid supplied to the substrate W, and thus the liquids may be separated and recovered. Unlike the description, the cup 420 may be fixedly installed, and the lifting unit 480 may move the support unit 440 in the vertical direction.

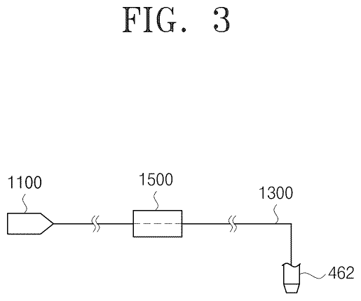

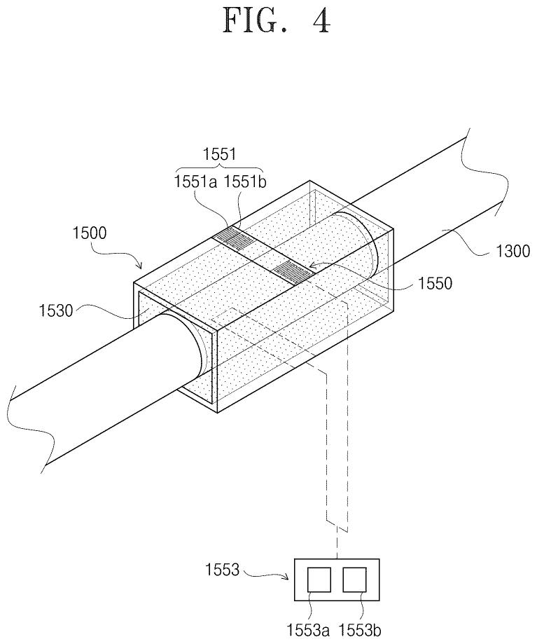

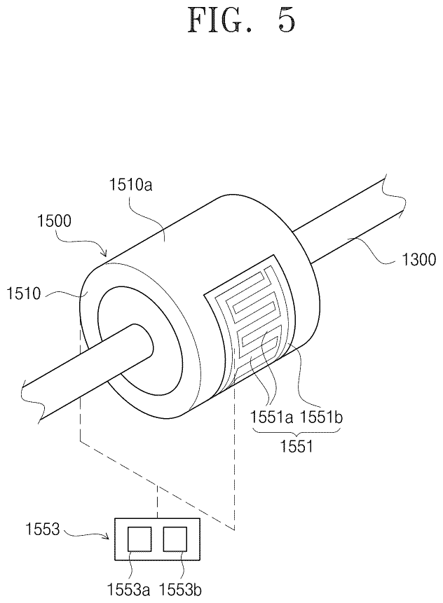

FIG. 3 is a diagram schematically illustrating an exemplary embodiment of the treatment liquid supply unit, FIG. 4 is a diagram schematically illustrating an exemplary embodiment of an acoustic wave applying module of FIG. 3, and FIG. 5 is a diagram schematically illustrating another exemplary embodiment of the acoustic wave applying module of FIG. 3. Referring to FIGS. 3 to 5, the treatment liquid supply unit 1000 supplies a treatment liquid to a first nozzle 462. The treatment liquid supply unit 1000 may include a treatment liquid tank 1100, a treatment liquid supply line 1300, and an acoustic wave applying module 1500. The treatment liquid tank 1100 stores a treatment liquid. The treatment liquid supply line 1300 connects the treatment liquid tank 1100 to the first nozzle 462. A pump, a valve, and the like, which are not illustrated, may be installed in the treatment liquid supply line 1300. The treatment liquid stored in the treatment liquid tank 1100 may be supplied to the first nozzle 462 through the treatment liquid supply line 1300. The treatment liquid supply line 1300 may be provided as a circular pipe having a circular cross section. Also, the material of the treatment liquid supply line 1300 may be PFA or PTFE.

The acoustic wave applying module 1500 may apply an acoustic wave to the treatment liquid. The acoustic wave applying module 1500 may be installed on the treatment liquid supply line 1300. Furthermore, the acoustic wave applying module 1500 may be installed to surround the treatment liquid supply line 1300. The acoustic wave applying module 1500 may include a case 1510, a medium 1530, and an acoustic wave generating unit 1550.

The case 1510 may surround the treatment liquid supply line 1300. A side surface 1510a of the case may be a flat surface or a curved surface. Referring to FIG. 4, when the side surface 1510a of the case is a flat surface, the case 1510 may be provided in a polygonal column shape. According to an example, the case 1510 may be provided in a rectangular column shape having the same longitudinal direction as the treatment liquid supply line 1300. The case 1510 may be provided in a rectangular column shape having the longitudinal direction of the treatment liquid supply line 1300.

Referring to FIG. 5, when the side surface 1510a of the case is curved, the case 1510 may be provided in a circular column shape having the same longitudinal direction as the treatment liquid supply line 1300. In addition, the case 1510 is provided in a shape in which the inside is empty. The case 1510 may be made of a material that facilitates transmitting acoustic waves. According to an example, the case 1510 may be made of a glass material.

A medium 1530 is provided inside the case 1510. The inside of the case 1510 may be filled with the medium 1530. The medium 1530 allows the acoustic wave generated by the acoustic wave generating unit 1550 to be transmitted to the treatment liquid flowing through the treatment liquid supply line 1300. The medium 1530 is preferably made of a material that prevents total reflection of acoustic waves and minimizes refraction. According to an exemplary embodiment, the medium 1530 may be glycerol.

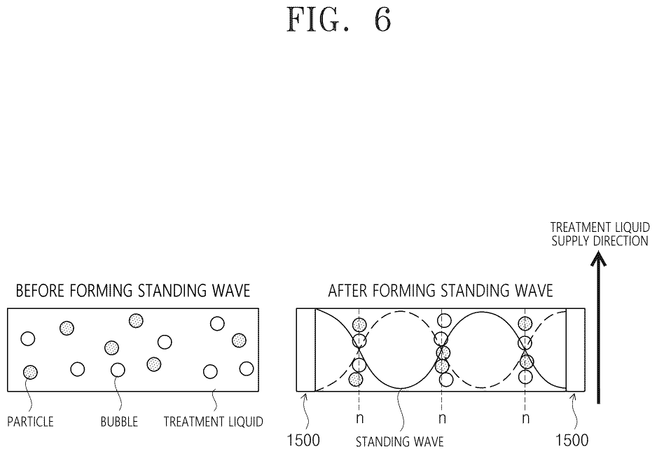

The acoustic wave generating unit 1550 may be installed on the side surface 1510a of the case. The acoustic wave generating unit 1550 may generate an acoustic wave. The acoustic wave generated by the acoustic wave generating unit 1550 may be transmitted to the treatment liquid supply line 1300 through the medium 1530. A plurality of acoustic wave generating units 1550 may be provided. Also, the acoustic wave generating units 1550 may be installed to face each other. A plurality of acoustic wave generating units 1550 may be installed so that acoustic waves applied by the respective acoustic wave generating units 1550 form a standing wave. The standing wave provides acoustic radiation force to foreign substances, such as particles and bubbles, (hereinafter, referred to as “particles and the like”) in the treatment liquid flowing along the treatment liquid supply line 1300. Particles and the like are moved to the node n of the standing wave by acoustic radiation force. At the node n, particles and the like may maintain a physically stable state and minimize energy, so that the particles and the like stay at the node n. FIG. 6 is a diagram illustrating an effect on particles and the like in a treatment liquid when a standing wave is formed in the treatment liquid. Referring to FIG. 6, particles and the like are moved to the node n of the standing wave by the acoustic radiation force represented by following Equation 1, and the acoustic radiation force and the drag force are in balance at the node n. Here, the drag force is generated by the flow of the treatment liquid, and is expressed by following

### Equation 2.

$${F}_{acoustic} = \frac{k ρπ {P}^{2} R}{1 - \frac{{ω}_{0}^{2}}{{ω}^{2}}} sin ( 2 kx ) \qquad [ Equation 1 ]$$

(where F_{acoustic}: acoustic radiation force, k: wave number, P: pressure, ρ: fluid density, R: radius of particle and the like, ω: acoustic wave frequency, ω₀: resonant frequency)

$${F}_{d r a g} = - 6 π μ R {v}_{x} \qquad [ Equation 2 ]$$

(where F_{drag}: drag force, μ: viscosity of treatment liquid, vₓ: speed of particles and the like)

Accordingly, particles in the treatment liquid may be induced to be aggregated by using the acoustic wave generating unit 1550.

The acoustic wave generating unit 1550 may include an acoustic wave generating part 1551 and an electric signal applying part 1553. Also, the acoustic wave generating part 1551 may include a piezoelectric member 1551a and a base 1551b.

The piezoelectric member 1551a may be formed of a material having piezoelectric properties. The piezoelectric member 1551a may serve as an electrode. The piezoelectric member 1551a repeatedly expands and contracts by an AC voltage applied by the electric signal applying part 1553 to be described later. According to an example, the piezoelectric member 1551a may be provided in a pattern shape in which the first electrode and the second electrode alternately cross each other.

The base 1551b provides a place where the piezoelectric member 1553a is formed. The piezoelectric member 1553a may be formed in a manner of being deposited on the base 1551b. The piezoelectric member 1553a may generate vibration by transmitting a mechanical deformation generated when the piezoelectric member 1553a expands and contracts due to a voltage to the base 1551b. Accordingly, the base 1551b is preferably made of a material capable of converting the mechanical deformation of the piezoelectric member 1553a into mechanical vibration. Accordingly, the mechanical vibration may be performed in synchronization with the acoustic wave frequency. Further, the piezoelectric member 1553a may be made of a material having flexibility. According to an example, the piezoelectric member 1553a may be made of a polyvinylidene fluoride (PVDF), an inorganic crystal thin film material, or the like. Accordingly, even when the side surface 1510a of the case is curved, the piezoelectric member 1553a may be stably installed.

The electric signal applying part 1553 may apply the electric signal to the acoustic wave generating part 1551. When the electric signal is applied to the acoustic wave generating part 1551, mechanical deformation (expansion or contraction) is caused by piezoelectricity. When the electric signal is an AC voltage, repeated deformation occurs according to the AC frequency, and accordingly, the acoustic wave generating part 1551 may generate an acoustic wave. Also, the electric signal applying part 1553 may include a frequency adjusting unit 1553a and a phase adjusting unit 1553b.

The frequency adjusting unit 1553a may adjust the frequency of the AC voltage. When the frequency of the AC voltage is changed, the frequency adjusting unit 1553a may adjust the frequency of the standing wave because the frequency of the standing wave is also changed. The frequency adjusting unit 1553a may adjust the frequency according to the size of the particles and the like to be removed. According to an example, as the frequency increases, the aggregation of fine particles may be induced.

The phase adjusting unit 1553b may adjust a phase of the AC voltage. When the phase of the AC voltage is changed, the phase of the standing wave formed is also changed, so that the phase adjusting unit 1553a may adjust a phase of the standing wave. By adjusting the phase of the standing wave in the phase adjusting unit 1553b, the node n of the standing wave may be moved, and particles and the like aggregated in the node n may be moved. Aggregated particles and the like may be provided to be removed to the outside by a removal means which is not illustrated. According to an example, the removal means may be a removal pipe connected to the treatment liquid supply line. Also, by adjusting the phase, stability of the standing wave may be improved, and collection of particles and the like may be efficiently performed.

The controller 900 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

Hereinafter, a method of processing a substrate will be described. The substrate processing method described below may be performed by the substrate processing apparatus described with reference to FIGS. 1 to 6. Accordingly, hereinafter, a substrate processing method according to an exemplary embodiment will be described by referring to reference numerals illustrated in FIGS. 1 to 6. In addition, the substrate processing method described below may be performed by controlling, by the controller, the configurations included in the substrate processing apparatus described above.

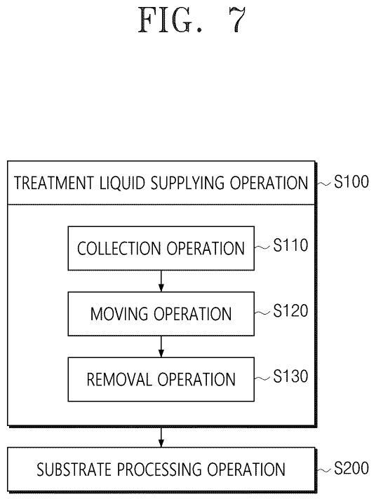

FIG. 7 is a flowchart illustrating a substrate processing method according to an exemplary embodiment of the present invention. Referring to FIG. 7, the substrate processing method may include a treatment liquid supplying operation S100 and a substrate processing operation S200.

The treatment liquid supplying operation S100 is an operation of supplying the treatment liquid to the treating chamber 400. In the treatment liquid supplying operation S100, the treatment liquid is supplied through the treatment liquid supply line 1300. The treatment liquid supplying operation S100 may include a collection operation S110, a moving operation S120, and a removal operation S130.

The collection operation S110 is an operation of collecting particles and the like in the treatment liquid. In the collection operation S110, the acoustic wave generating unit 1550 generates an acoustic wave. The generated acoustic wave is transmitted to the treatment liquid supply line 1300 through the medium 1530. The acoustic wave passes through the treatment liquid flowing through the treatment liquid supply line 1300. While the acoustic wave passes through the treatment liquid, the acoustic wave provides acoustic radiation force to particles and the like in the treatment liquid. Particles and the like may be moved by acoustic radiation force. The acoustic wave may form a standing wave in the treatment liquid supply line 1300 while being reflected when the acoustic wave meets the treatment liquid supply line 1300. When the standing wave is formed, particles and the like may be collected at the node n of the standing wave by acoustic radiation force. In addition, the frequency of the acoustic wave may be determined by the frequency adjusting unit 1553a. The frequency adjusting unit 1553a may set the frequency according to the size and properties of particles and the like to be collected. In addition, as described above, when the side surface 1510a of the case is provided to be curved, acoustic waves may be transmitted in a plurality of radial directions of the treatment liquid supply line 1300. According to an example, acoustic waves may be applied in opposite directions based on particles and the like. Accordingly, collection of particles and the like may be performed more efficiently.

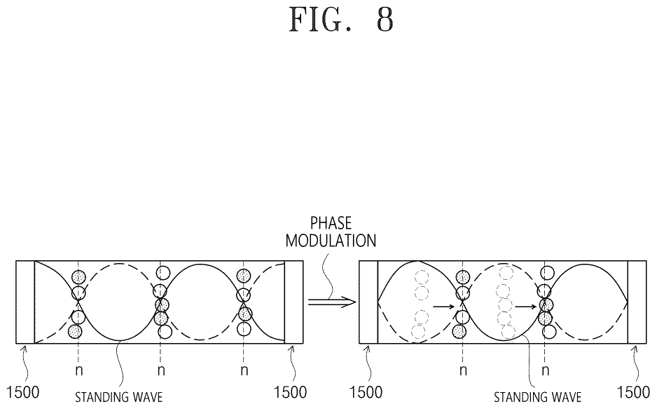

FIG. 8 is a diagram illustrating a process of moving particles and the like in the moving operation. Referring to FIG. 8, in the moving operation S120, the collected particles and the like are moved. According to an example, the collected particles and the like may be moved to be removed to the outside in the moving operation S120. The collected particles and the like may be fluctuated together as the position of the node n of the standing wave is changed. The node n of the standing wave may be changed by adjusting the phase in the phase adjusting unit 1553b. By moving the node n of the standing wave in the moving operation S100, particles and the like may be efficiently collected and easily removed.

The removal operation S130 is an operation of removing the collected particles and the like. The particles and the like moved in the moving operation S120 are removed in the removal operation S130. According to an example, particles and the like may be removed through a removing line (not illustrated) connected to the treatment liquid supply line 1300.

The substrate processing operation S200 is an operation of processing the substrate W with a treatment liquid. Since the treatment liquid is a treatment liquid that has passed through the treatment liquid supplying operation S100, defects occurring on the substrate W by the treatment liquid may be minimized.

According to the exemplary embodiment of the present invention, it is possible to minimize the sound pressure phenomenon at the pump that occurs when the filter is used, by removing particles and the like by applying acoustic waves without using a filter. Accordingly, it is possible to stably supply the treatment liquid even with a relatively low performance pump.

In addition, the complexity of the apparatus structure and process progress may be eliminated by improving the cleanliness of the treatment liquid by removing particles with a simplified configuration without using a separate device to remove particles and the like.

In the above-described exemplary embodiment, the method is described based on a flowchart as a series of operations or blocks, but the present invention is not limited to the order of operations, and some operations may occur in a different order or simultaneously with other operations as described above. In addition, those skilled in the art will understand that the operations illustrated in the flowchart are not exclusive and that other operations may be included or one or more operations in the flowchart may be deleted without affecting the scope of the present invention.

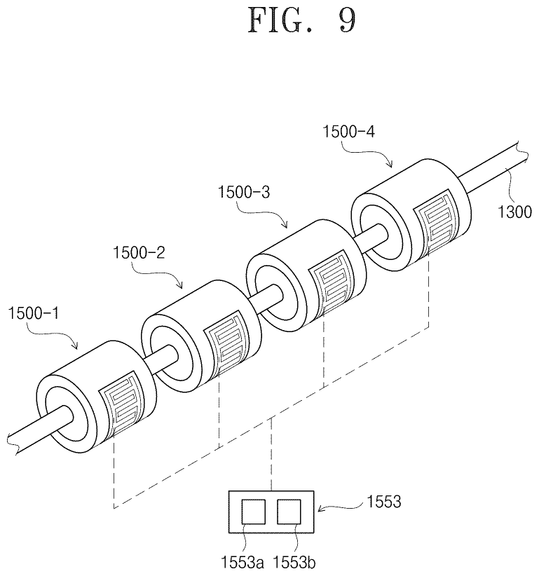

In the above-described example, the present invention has been described based on the case where the single acoustic wave applying module 1500 is provided as an example. However, the present invention is not limited thereto, and a plurality of acoustic wave applying modules 1500 may be provided. According to an example, as illustrated in FIG. 9, four acoustic wave applying modules 1500 may be provided. Accordingly, it is possible to further improve the cleanliness of the liquid by increasing the amount of particles and the like collected in the liquid.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

1. An apparatus for processing a substrate, the apparatus comprising:
a treating chamber for processing a substrate with a treatment liquid; and
a treatment liquid supply unit for supplying the treatment liquid to the treating chamber,
wherein the treatment liquid supply unit includes:
a treatment liquid tank for storing the treatment liquid;
a treatment liquid supply line for connecting the treatment liquid tank and the treating chamber; and
an acoustic wave applying module which is installed in the treatment liquid supply line and applies an acoustic wave to the treatment liquid supply line to improve cleanliness of the treatment liquid.

2. The apparatus of claim 1, wherein the acoustic wave applying module includes:
a case surrounding the treatment liquid supply line;
an acoustic wave generating part installed in the case; and
a medium provided inside the case.

3. The apparatus of claim 2, wherein the acoustic wave generating part is provided to form a standing wave in the treatment liquid supply line.

4. The apparatus of claim 3, wherein the acoustic wave generating part is provided in plural and is continuously installed.

5. The apparatus of claim 4, wherein the acoustic wave generating part includes: a phase adjusting unit provided to adjust a phase of the acoustic wave.

6. The apparatus of claim 5, wherein the case is provided in a cylindrical shape with a curved surface, and
the acoustic wave generating part is made of a polymer material having flexibility and piezoelectricity, and is installed on the curved surface.

7. The apparatus of claim 5, wherein the case is provided in a cylindrical shape with a curved surface, and
the acoustic wave generating part is made of an inorganic crystal thin film material having piezoelectricity and is installed on the curved surface.

8. The apparatus of claim 5, further comprising:
a controller,
wherein the controller determines a wavelength of an acoustic wave generated by the acoustic wave generating part according to a type of particles present in the treatment liquid.

9. The apparatus of claim 5, further comprising:
a controller,
wherein the controller controls the acoustic wave applying module to perform:
a collection operation of collecting particles and bubbles in the treatment liquid by generating an acoustic wave in the acoustic wave generating part when supplying the treatment liquid; and
a moving operation of moving the collected particles and bubbles by adjusting a phase of the acoustic wave in the phase adjusting unit.

10. The apparatus of claim 9, wherein after the moving operation, the acoustic wave applying module is controlled to perform a removal operation of removing the particles and bubbles moved after collection.

11.-16. (canceled)

17. An apparatus for processing a substrate, the apparatus comprising:
a treating chamber for processing a substrate with a treatment liquid; and
a treatment liquid supply unit for supplying the treatment liquid to the treating chamber,
wherein the treatment liquid supply unit includes:
a treatment liquid tank for storing the treatment liquid;
a treatment liquid supply line for connecting the treatment liquid tank and the treating chamber; and
an acoustic wave applying module which is installed in the treatment liquid supply line and applies an acoustic wave to the treatment liquid supply line to improve cleanliness of the treatment liquid;
a removal line for removing particles collected by the acoustic wave applying module to the outside; and
a controller,
the acoustic wave applying module includes:
a case surrounding the treatment liquid supply line;
an acoustic wave generating part installed in the case;
a phase adjusting unit configured to adjust a phase of the acoustic wave, and
a medium provided inside the case,
the acoustic wave generating part is provided to form a standing wave in the treatment liquid supply line and adjust a phase of the acoustic wave, and
the controller controls the acoustic wave applying module to perform:
a collection operation of collecting particles and bubbles in the treatment liquid by generating an acoustic wave in the acoustic wave generating part when supplying the treatment liquid; and
a moving operation of moving the collected particles and bubbles to an inner wall of the treatment liquid supply line by adjusting a phase of the acoustic wave in the phase adjusting unit.

18. The apparatus of claim 17, wherein the acoustic wave generating part is provided to form a standing wave in the treatment liquid supply line.

19. The apparatus of claim 17, wherein the case is provided in a cylindrical shape with a curved surface, and
the acoustic wave generating part is made of a polymer material or an inorganic crystal thin film material having flexibility and piezoelectricity, and is installed on the curved surface.

20. The apparatus of claim 17, wherein a wavelength of an acoustic wave generated by the acoustic wave generating part is determined according to a type of particles and bubbles present in the treatment liquid.
